(19) United States
(12) Patent Application Publication
(10) Pub. No.: US 2026/0125313 A1
(43) Pub. Date: May 7, 2026

(54) Method of Preparing a Perovskite Film

(71) Applicant: Nanyang Technological University, Singapore (SG)

(72) Inventors: Annalisa BRUNO, Singapore (SG); Herlina Arianita DEWI, Singapore (SG); Subodh Gautam MHAISALKAR, Singapore (SG); Erdenebileg ENKHTUR, Singapore (SG)

(21) Appl. No.: 19/379,921

(22) Filed: Nov. 5, 2025

(30) Foreign Application Priority Data
Nov. 5, 2024 (SG) 10202403420X

(51) Int. Cl. C03C 17/22; H10K 30/40; H10K 30/50

(52) U.S. Cl. CPC C03C 17/22; H10K 30/40; H10K 30/50; C03C 2217/284; C03C 2218/151

(57) ABSTRACT

The present disclosure broadly relates to a method of depositing a perovskite film on a substrate, the perovskite having a formula ABX₃. The method may comprise the step of co-evaporating a compound of formula AX and a compound of formula BX₂ onto the substrate, wherein: A is selected from one or more monovalent metal cations or organic cations; B is selected from one or more metal cations or metalloid cations; and X is selected from one or more halide anions or pseudohalide anions. There is also disclosed herein a perovskite film produced by the method as well as a photovoltaic cell comprising the perovskite film.

### CROSS-REFERENCE TO RELATED APPLICATION

This application claims the benefit of Singapore Application No. 10202403420X filed with the Intellectual Property Office of Singapore on Nov. 5, 2024, the entire contents of which are incorporated herein by reference.

### TECHNICAL FIELD

The present invention generally relates to a method of preparing a perovskite film. The present invention also relates to a perovskite film prepared by the method and use of the perovskite film in a photovoltaic cell.

### BACKGROUND ART

Perovskite solar cells (PSCs) have emerged as attractive alternative solar cell materials, thanks to their exceptional power conversion efficiencies, low-cost fabrication processes, and versatility in design. Different perovskite fabrication routes have been established, which are broadly categorized into solution-processable deposition or vacuum deposition. Solution-processable deposition has been the most commonly used deposition route and may be considered the most efficient perovskite fabrication method, with PSCs produced by this method having the highest power conversion efficiencies (PCE) in the range of 26%. Despite the high PCE, toxic solvents and limited scalability are major considerations for adapting the technique to large-scale industrial production. In contrast, vacuum deposition has generally been used industrially, particularly in light-emitting display devices. As such, there are prospects for integrating perovskite deposition processes with vacuum deposition processes. However, the slow co-evaporation involved with vacuum deposition is a major obstacle to commercialization, with the fastest recorded deposition times at about 50 minutes, ranging to hours for multiple vacuum deposition steps. Moreover, a common step required in perovskite fabrication is post-annealing, which may substantially add to the manufacturing time and increase power consumption.

There is thus a need for a method of producing a perovskite film using vacuum deposition that, for example, are more time-efficient, where the produced perovskite films have good PCE results, and/or where the method does not require post-annealing.

Accordingly, there is a need for a method of producing a perovskite film using a vacuum deposition process that overcomes, or at least ameliorates, one or more of the disadvantages mentioned above.

### SUMMARY

According to a first aspect, there is provided a method of depositing a perovskite film on a substrate, the perovskite having a formula ABX₃, the method comprising the step of co-evaporating a compound of formula AX and a compound of formula BX₂ onto the substrate,
wherein:
   A is selected from one or more monovalent metal cations or organic cations;
   B is selected from one or more metal cations or metalloid cations; and
   X is selected from one or more halide anions or pseudohalide anions.

Advantageously, the method as described herein may provide a relatively fast means of producing a perovskite film, which may reduce the fabrication time. Advantageously, the vacuum deposition method may substantially avoid the use of solvents, reducing costs and environmental impact.

According to a second aspect, there is provided a perovskite film produced by the method as described herein.

Advantageously, the perovskite film as described herein may not need to be post-annealed to the substrate after being produced.

According to a third aspect, there is provided a photovoltaic cell comprising the perovskite film as described herein.

Advantageously, the photovoltaic cell comprising the perovskite film as described herein may provide good power conversion efficiency (PCE) characteristics.

### BRIEF DESCRIPTION OF DRAWINGS

The accompanying drawings illustrate a disclosed embodiment and serve to explain the principles of the disclosed invention. It is to be understood, however, that the drawings are designed for purposes of illustration only, and not as a definition of the limits of the invention.

FIG. 1 is a schematic showing the setup for a method of depositing a perovskite film on a substrate according to one embodiment.

FIG. 2 is a graph showing deposition rates of different deposition times from 150 to 25 minutes.

FIG. 3 is a schematic showing a device configuration which incorporates the co-deposited MAPbI₃ perovskite film.

FIG. 4 is a graph showing the power conversion efficiency (PCE) of a co-evaporated MAPbI₃ perovskite film using different deposition times from 150 to 25 minutes.

FIG. 5 is a graph showing the photovoltaic parameters: open-circuit voltage (Voc), short-circuit current density (Jsc), and fill factor (FF) of different deposition times from 150 to 25 minutes.

FIG. 6 is a composite graph showing photovoltaic parameters: PCE, Voc, Jsc, and FF of co-evaporated perovskite solar cells incorporating MAPbI₃ film as-deposited (without annealing) and MAPbI₃ film after post-annealing at 100° C. for 30 minutes.

FIG. 7A is a graph showing a Tauc plot of co-evaporated MAPbI₃ perovskite films produced using a co-evaporation deposition time of 150 minutes and 25 minutes.

FIG. 7B shows XRD patterns of co-evaporated MAPbI₃ perovskite films produced using a co-evaporation deposition time of 150 minutes and 25 minutes.

FIG. 8A is a graph showing an absorbance plot for MAPbI₃ perovskite films produced using varying co-evaporation deposition times.

FIG. 8B is a graph showing a Tauc plot for MAPbI₃ perovskite films produced using varying co-evaporation deposition times.

FIG. 8C shows XRD patterns for MAPbI₃ perovskite films produced using varying co-evaporation deposition times.

FIG. 9A shows a field emission scanning electron microscopy (FESEM) image, at magnification of 50,000×, of a top view and cross-sectional view of MAPbI₃ perovskite film produced using a deposition time of 150 minutes.

FIG. 9B shows a FESEM image, at magnification of 50,000×, of a top view and cross-sectional view of MAPbI₃ perovskite film produced using a deposition time of 25 minutes.

FIG. 10A is a schematic showing the setup for co-evaporating MAPbI₃ films at different source-to-substrate distances (23 cm and 30 cm)

FIG. 10B is a graph showing the absorbance of co-deposited MAPbI₃ films obtained at different source-to-substrate distances (23 cm and 30 cm).

FIG. 10C is a graph showing the Voc characteristics of co-deposited MAPbI₃ films obtained at different substrate-source distances (23 cm and 30 cm).

FIG. 10D is a graph showing the Jsc characteristics of co-deposited MAPbI₃ films obtained at different substrate-source distances (23 cm and 30 cm).

FIG. TOE is a graph showing the FF characteristics of co-deposited MAPbI₃ films obtained at different substrate-source distances (23 cm and 30 cm).

FIG. 10F is a graph showing the PCE characteristics of co-deposited MAPbI₃ films obtained at different substrate-source distances (23 cm and 30 cm).

FIG. 11 is a graph showing the comparison between PCE values of the present invention and those of previously disclosed work.

### DEFINITIONS

The following words and terms used herein shall have the meaning indicated:

As used herein, the singular forms “a”, “an”, and “the” designate both the singular and the plural, unless expressly stated to designate the singular only.

The word “substantially” does not exclude “completely” e.g. a composition which is “substantially free” from Y may be completely free from Y. Where necessary, the word “substantially” may be omitted from the definition of the invention.

Unless specified otherwise, the terms “comprising” and “comprise”, and grammatical variants thereof, are intended to represent “open” or “inclusive” language such that they include recited elements but also permit inclusion of additional, unrecited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value. Moreover, “about” may be understood by persons of ordinary skill in the art to allow for small or non-substantial variations reflecting the appropriate level of precision according

Throughout this disclosure, certain embodiments may be disclosed in a range format. It should be understood that the description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

As used herein, the term “about” and the use of ranges in general, whether or not qualified by the term about, means that the number comprehended is not limited to the exact number set forth herein, and is intended to refer to values substantially within the quoted range while not departing from the scope of the invention.

The term “Voc” (open-circuit voltage) refers to the maximum voltage that a photovoltaic cell or device can produce when no current is flowing.

The term “Jsc” (short-circuit current density) refers to the current per unit area generated by a photovoltaic cell when the external voltage is zero.

The term “FF” (fill factor) refers to the “squareness” of the current-voltage (J-V) curve of a photovoltaic cell. The FF is calculated using the formula: FF=(V_{MP}×J_{MP})/(V_{OC}×J_{SC}), wherein V_{MP} is the voltage at the maximum power point (MPP) and J_{MP} is the current density at the MPP.

A Tauc plot refers to a graphical method used to determine the optical bandgap (Eg) of a film or semiconductor from its absorption data.

The terms “evaporation”, “co-evaporation”, “deposition” and “co-deposition” are directed to the process of evaporating the precursors, wherein the precursors are concurrently or successively deposited onto the substrate to form a deposited film. As these processes occur concurrently or in immediate succession to one another, the terms “evaporation”, “co-evaporation”, “deposition” and “co-deposition” may be used interchangeably and refer to substantially the same process.

Certain embodiments may also be described broadly and generically herein. Each of the narrower species and subgeneric groupings falling within the generic disclosure also form part of the disclosure. This includes the generic description of the embodiments with a proviso or negative limitation removing any subject matter from the genus, regardless of whether or not the excised material is specifically recited herein.

### Detailed Disclosure of Embodiments

Exemplary, non-limiting embodiments of a method of depositing a perovskite film will now be disclosed.

In the method of depositing the perovskite film on a substrate, the perovskite having a formula ABX₃, the method comprises the step of co-evaporating a compound of formula AX and a compound of formula BX₂ onto the substrate,
wherein:
   A is selected from one or more monovalent metal cations or organic cations;
   B is selected from one or more metal cations or metalloid cations; and
   X is selected from one or more halide anions or pseudohalide anions.

A may be selected from a monovalent metal cation or an organic cation. A may be selected from Cs⁺, Rb⁺, K⁺, CH₃NH₃⁺, [HC(NH)₂)₂]⁺, ethylammonium, guanidinium, or a combination thereof. A may be selected from Cs⁺, CH₃NH₃⁺ or [HC(NH)₂)₂]⁺, or a combination thereof.

B may be selected from a metal cation or a metalloid cation. B may be selected from Pb²⁺, Sn²⁺, Ge²⁺, Be²⁺, Mn²⁺, Cu²⁺, Sb²⁺, or a combination thereof. B may be selected from Pb²⁺, Sn²⁺, Ge²⁺, Be²⁺, Sb²⁺ or a combination thereof.

X may be selected from a halide anion or a pseudohalide anion. X may be selected from Cl⁻, Br⁻, I⁻, SCN⁻, CN⁻, or a combination thereof. X may be selected from Cl⁻, Br⁻ or I⁻, or a combination thereof.

AX may be CH₃NH₃I. BX₂ may be PbI₂. ABX₃ may be CH₃NH₃PbI₃.

The co-evaporating step may be undertaken for a time duration of less than about 90 minutes, or less than about 75 minutes, or less than about 60 minutes, or less than about 50 minutes, or less than about 40 minutes, or less than about 35 minutes, or less than about 30 minutes, or less than about 25 minutes, or less than about 20 minutes, or less than about 15 minutes, or less than about 10 minutes, or less than about 5 minutes. The co-evaporating step may be undertaken for a time duration of between about 5 minutes to about 90 minutes, or between about 5 minutes to about 75 minutes, or between about 5 minutes to about 60 minutes, or between about 5 minutes to about 50 minutes, or between about 10 minutes to about 40 minutes, or between about 15 minutes to about 35 minutes, or between about 20 minutes to about 35 minutes, or between about 20 minutes to about 30 minutes. It is to be appreciated that the above ranges should be interpreted as including and supporting any sub-ranges or discrete values (which may or may not be a whole number) that are within the stated range(s).

The co-evaporating step may comprise the step (a1) of heating the compound of formula AX to a predetermined temperature. The predetermined temperature may have an upper limit that is dependent on the degradation temperature of AX. The co-evaporating step may comprise the step (a1) of heating the compound of formula AX to a temperature of over about 60° C., or over about 70° C., or over about 80° C., or over about 90° C., or over about 100° C., or over about 110° C., or over about 120° C., or over about 130° C., or over about 135° C., or over about 140° C., or over about 145° C., or over about 150° C., or over about 155° C. The aforementioned temperatures may have an upper limit which is at or near the degradation temperature of AX. The co-evaporating step may comprise the step (a1) of heating the compound of formula AX to a temperature of between about 60° C. to about 700° C., or between about 70° C. to about 600° C., or between about 80° C. to about 500° C., or between about 90° C. to about 400° C., or between about 100° C. to about 300° C., or between about 110° C. to about 250° C., or between about 120° C. to about 200° C., or between about 130° C. to about 180° C., or between about 135° C. to about 170° C., or between about 140° C. to about 180° C., or between about 145° C. to about 170° C., or between about 150° C. to about 160° C. It is to be appreciated that the above ranges should be interpreted as including and supporting any sub-ranges or discrete values (which may or may not be a whole number) that are within the stated range(s).

The co-evaporating step may comprise the step (a2) of heating the compound of formula BX₂ to a predetermined temperature. The predetermined temperature may have an upper limit that is dependent on the degradation temperature of BX₂. The co-evaporating step may comprise the step (a2) of heating the compound of formula BX₂ to a temperature of over about 200° C., or over about 225° C., or over about 250° C., or over about 275° C., or over about 300° C., or over about 325° C., or over about 350° C., or over about 375° C., or over about 380° C., or over about 385° C., or over about 390° C., or over about 391° C., or over about 392° C., or over about 393° C., or over about 394° C., or over about 395° C. The aforementioned temperatures may have an upper limit which is at or near the degradation temperature of BX₂. The co-evaporating step may comprise the step (a2) of heating the compound of formula BX₂ to a temperature of between about 200° C. to about 600° C., or between about 225° C. to about 550° C., or between about 250° C. to about 525° C., or between about 250° C. to about 500° C., or between about 275° C. to about 500° C., or between about 300° C. to about 475° C., or between about 325° C. to about 450° C., or between about 350° C. to about 425° C., or between about 375° C. to about 400° C., or between about 380° C. to about 395° C., or between about 385° C. to about 395° C., or between about 390° C. to about 395° C. It is to be appreciated that the above ranges should be interpreted as including and supporting any sub-ranges or discrete values (which may or may not be a whole number) that are within the stated range(s).

The method of depositing the perovskite film on the substrate may be conducted in a low-pressure chamber. The low-pressure chamber may be a vacuum chamber. The vacuum chamber may be operated at a pressure maintained between about 1×10⁻⁵ Pa to about 1×10⁻² Pa, or between about 5×10⁻⁵ Pa to about 5×10⁻³ Pa, or between about 1×10⁻⁴ Pa to about 1×10⁻⁸ Pa, or between about 3×10⁻⁴ Pa to about 8×10⁻⁴ Pa, or between about 5×10⁻⁴ Pa to about 7×10⁻⁴ Pa. It is to be appreciated that the above ranges should be interpreted as including and supporting any sub-ranges or discrete values (which may or may not be a whole number) that are within the stated range(s). The pressure may be monitored and maintained at a desired pressure during the deposition. The pressure may be monitored and adjusted as required during the deposition.

One of both of the AX and BX₂ degradation temperatures may be highly dependent on the chamber pressure. When the chamber pressure is low, the decomposition of one or both of AX and BX₂ may be prevented, therefore enabling an accelerated deposition rate. The chamber pressure may also be maintained at a constant value while systematically varying the temperature so as to accelerate the deposition process without causing compound degradation. As the chamber pressure and the evaporation temperature of the precursors may be interdependent, lowering the evaporation pressure may allow for the possibility to evaporate the precursors at a lower temperature, thereby substantially avoiding degradation. The perovskite precursors AX and BX₂, such as in the form of CH₃NH₃I and PbI₂, may be thermally sensitive and may decompose if the temperature exceeds a certain value. By controlling the deposition pressure at a specific value, it may be possible to assess the evaporation temperature, which will impact the evaporation rate, and thereby determine the precise point at which the precursor begins to degrade. It was surprisingly found that a balance between working pressure and temperature, optionally along with other parameters such as source/crucible material, volume and/or amount of AX and BX₂ used, ratio of AX to BX₂, design of thermal evaporator, distances between the source/sources and sensor rate monitor, distances between the source/sources and substrate, evaporator chamber pressure profile, and deposition rate during co-evaporation, may advantageously produce deposited perovskite films having desired photovoltaic properties.

The mole ratio of the compound of formula AX to the compound of formula BX₂ may be between about 8:1 to about 1:2, or between about 4:1 to about 1:1, or between about 3:1 to about 4:3, or between about 5:2 to about 5:3. The mole ratio of the compound of formula AX to the compound of formula BX₂ may be about 2:1. With respect to the AX to BX₂ ratio of 2:1, there may be small excess in either AX or BX₂. The small excess of AX or BX₂ may be about 0.1% to about 5%, relative to the AX to BX₂ ratio of 2:1. It is to be appreciated that the above ranges should be interpreted as including and supporting any sub-ranges or discrete values (which may or may not be a whole number) that are within the stated range(s).

The perovskite film may be deposited onto the substrate at a deposition rate of greater than about 5 nm/minute, or greater than about 8 nm/minute, or greater than about 10 nm/minute, or greater than about 15 nm/minute, or greater than about 20 nm/minute, or greater than about 22 nm/minute, or greater than about 24 nm/minute, or greater than about 26 nm/minute, or greater than about 28 nm/minute, or greater than about 30 nm/minute. The perovskite film may be deposited on the substrate at a deposition rate of between about 5 nm/minute to about 40 nm/minute, or between about 10 nm/minute to about 35 nm/minute, or between about 15 nm/minute to about 32 nm/minute, or between about 20 nm/minute to about 31 nm/minute, or between about 22 nm/minute to about 30 nm/minute, or between about 24 nm/minute to about 29 nm/minute, or between about 26 nm/minute to about 28 nm/minute. It is to be appreciated that the above ranges should be interpreted as including and supporting any sub-ranges or discrete values (which may or may not be a whole number) that are within the stated range(s).

During the co-evaporating step, the compound of formula AX and the compound of formula BX₂ may be placed on separate sources for co-evaporation. The sources may be crucibles. The crucibles may be cylindrical-shaped crucibles. The crucible materials may be independently selected from tungsten, molybdenum, tantalum, graphite, alumina, quartz, or ceramic material. The selection of crucible materials, crucible volume, and the amount of material located in the crucible may affect the temperature applied for each of AX and BX₂.

The compound of formula AX and the compound of formula BX₂ may be provided in the form of a powder. The quantities of AX and BX₂ may be determined according to the deposition conditions as described herein, as well as the size of the sources, for example, in the form of crucibles, to achieve a balance between the amount of the compounds required for deposition and adequate/uniform heating.

The distance between each source (for AX and BX₂) to the substrate is referred to as the source-to-substrate distance. The method may comprise the step of varying the distance from each source to the substrate (or source-to-substrate distance). The source-to-substrate distance may be between about 10 cm to about 50 cm, or between about 15 cm to about 40 cm, or between about 20 cm to about 30 cm. The AX source-to-substrate distance may be the same or different to the BX₂ source-to-substrate distance. It is to be appreciated that the above ranges should be interpreted as including and supporting any sub-ranges or discrete values (which may or may not be a whole number) that are within the stated range(s). The present deposition method may provide flexibility in varying the source-to-substrate distances to enable process acceleration, while previously disclosed deposition methods tend towards using fixed source-to-substrate distances.

The substrate onto which the perovskite film is deposited may be a glass, a polymer, a metal, an oxide, or a ceramic. The glass may be a coated glass. The coating may be indium tin oxide (ITO) or fluorine-doped tin oxide (FTO).

The method may not comprise a step of post-annealing the deposited perovskite film to the substrate.

Alternatively, the method as described herein may include a post-annealing step. Post-annealing may be performed to improve the crystallinity and phase purity of a perovskite layer. Post-annealing such as thermal treatment may promote grain growth, reduce residual solvents, and facilitate complete conversion of the precursor into the perovskite phase. Post-annealed films may exhibit enhanced carrier mobility, reduced defect density, and improved interfacial contact with adjacent layers.

It has been surprisingly found that during the deposition, any one or more of the following perovskite film properties such as thickness, grain size, growth orientation and optical properties, may be controlled by carefully adjusting the co-evaporation parameters (such as heating temperatures, source/crucible material, volume and/or amount of AX and BX₂ used, design of thermal evaporator, distances between the source/sources and sensor rate monitor, distances between the source/sources and substrate, evaporator chamber pressure profile, and deposition rate during co-evaporation). These parameters may be adjusted such that the photovoltaic properties of the perovskite may be substantially retained. The perovskite film properties may be observed through analysing characteristics and properties such as grain size, absorbance, XRD pattern, and photoluminescence.

Exemplary, non-limiting embodiments of the perovskite film produced by the method as described herein will now be disclosed.

The perovskite film produced by the method as described herein may be used substantially without any post-annealing step. Alternatively, the perovskite film produced by the method as described herein may be subjected to a post-annealing step. The post-annealing step may comprise thermal annealing, solvent-vapor annealing, flash annealing, vacuum annealing, or a combination thereof.

The deposition time for producing a perovskite film produced by the method as described herein may be faster or accelerated compared to the deposition time required to produce a perovskite film of similar or equivalent thickness produced using other methods. The present deposition time may be at least about 5% faster than the deposition time for producing a perovskite film of similar or equivalent thickness produced using other methods, or at least about 10% faster, or at least about 15% faster, or at least about 20% faster, or at least about 25% faster, or at least about 30% faster, or at least about 35% faster, or at least about 40% faster, or at least about 45% faster, or at least about 50% faster. It is to be appreciated that the above ranges should be interpreted as including and supporting any sub-ranges or discrete values (which may or may not be a whole number) that are within the stated range(s).

The perovskite in the perovskite film produced by the method as described herein may have a grain size of between about 20 nm to about 300 nm, or between about 30 nm to about 250 nm, or between about 40 nm to about 200 nm, or between about 50 nm to about 180 nm, or between about 60 nm to about 160 nm, or between about 60 nm to about 140 nm, or between about 70 nm to about 120 nm, or between about 80 nm to about 100 nm. It is to be appreciated that the above ranges should be interpreted as including and supporting any sub-ranges or discrete values (which may or may not be a whole number) that are within the stated range(s).

The perovskite film produced by the method as described herein may have a thickness of between about 100 nm to about 1200 nm, or between about 200 nm to about 1100 nm, or between about 300 nm to about 1000 nm, or between about 400 nm to about 900 nm, or between about 500 nm to about 800 nm, or between about 600 nm to about 700 nm. It is to be appreciated that the above ranges should be interpreted as including and supporting any sub-ranges or discrete values (which may or may not be a whole number) that are within the stated.

The perovskite film produced by the method as described herein may have a surface roughness of from about 1 nm to about 100 nm, or from about 2 nm to about 50 nm, as determined by AFM. The roughness value may follow and/or be highly dependent on the roughness of the bottom substrate selection. The substrate may comprise a micron-sized pyramidal surface texture. The film may substantially cover the micron-sized pyramidal surface texture of the substrate. It is to be appreciated that the above ranges should be interpreted as including and supporting any sub-ranges or discrete values (which may or may not be a whole number) that are within the stated range(s).

The perovskite film produced by the method as described herein may have a photoluminescence lifetime of from about 25 ns to about 1000 ns, or from about 50 ns to about 500 ns, as determined by Time-Resolved Photoluminescence (TRPL). It is to be appreciated that the above ranges should be interpreted as including and supporting any sub-ranges or discrete values (which may or may not be a whole number) that are within the stated range(s).

The perovskite film produced by the method as described herein may comprise Pb, wherein the film may exhibit a Pb 4f_{7/2} peak from about 138.0 eV to about 139.0 eV, or from about 138.4 eV to about 138.7 eV, corresponding to Pb²⁺, as determined by X-Ray Photoelectron Spectroscopy (XPS). The perovskite film may comprise I, wherein the film may exhibit an I 3d_{s/2} peak from about 618.0 eV to about 619.5 eV, or from about 618.5 eV to about 619.0 eV, corresponding to I⁻, as determined by XPS. It is to be appreciated that the above ranges should be interpreted as including and supporting any sub-ranges or discrete values (which may or may not be a whole number) that are within the stated range(s).

Space-Charge-Limited Current (SCLC) measurements may be conducted on the hole-only or electron-only configuration, to monitor the hole or electron mobility of the absorbing species. The perovskite film produced by the method as described herein may independently have electron and hole mobility values from about 0.01 cm² V⁻¹s⁻¹ to about 20 cm² V⁻¹s⁻¹, or from about 0.01 cm² V⁻¹s⁻¹ to about 200 cm² V⁻¹s⁻¹, as determined by SCLC. It is to be appreciated that the above ranges should be interpreted as including and supporting any sub-ranges or discrete values (which may or may not be a whole number) that are within the stated range(s).

The perovskite film produced by the method as described herein may have a charge-transfer resistance of from about 1 to about 10⁶ Ω·cm², or from about 10 to about 10⁶ Ω·cm², or from about 10² to about 10⁶ Ω·cm², as determined by Electrochemical Impedance Spectroscopy (EIS). The EIS measurement may be done on the photovoltaic device to monitor the recombination resistance inside the photovoltaic cell. There may be a wide range in the values obtained, depending on the quality of the absorbing species. It is to be appreciated that the above ranges should be interpreted as including and supporting any sub-ranges or discrete values (which may or may not be a whole number) that are within the stated range(s).

The perovskite film produced by the method as described herein may have a carrier lifetime of from about 0.1 to about 100 μs, or from about 0.1 to about 30 μs, or from about 0.1 to about 10 μs, or from about 0.1 to about 2 μs, as determined by Transient Photovoltage/Photocurrent (TPV/TPC). The values may be sensitive to the structure of the device. It is to be appreciated that the above ranges should be interpreted as including and supporting any sub-ranges or discrete values (which may or may not be a whole number) that are within the stated range(s).

A photovoltaic cell comprising the perovskite film as described herein may be provided. The photovoltaic cell comprising the perovskite film may have a P-I-N or N-I-P configuration. The photovoltaic cell may be used to generate electric power from light.

The photovoltaic cell comprising the perovskite film as described herein may have a power conversion efficiency (PCE) of over about 5%, or over about 10%, or over about 12%, or over about 14%, or over about 15%, or over about 16%, or over about 17%, or over about 18%, or over about 19%, or over about 20%. The perovskite film produced by the method as described herein may have a PCE of between about 5% to about 30%, or between about between about 10% to about 25%, or between about 12% to about 22%, or between about 14% to about 20%, or between about 15% to about 19%, or between about 16% to about 18%. It is to be appreciated that the above ranges should be interpreted as including and supporting any sub-ranges or discrete values (which may or may not be a whole number) that are within the stated range(s).

The photovoltaic cell comprising the perovskite film as described herein may possess voltaic properties, such as power conversion efficiency (PCE), that are better than a perovskite film of similar or equivalent thickness produced using other methods. The present perovskite film may have a PCE value of at least about 5% higher than a perovskite film of similar or equivalent thickness produced using other methods, or at least about 10% higher, or at least about 15% higher, or at least about 20% higher, or at least about 25% higher, or at least about 30% higher, or at least about 35% higher, or at least about 40% higher, or at least about 45% higher, or at least about 50% higher. It is to be appreciated that the above ranges should be interpreted as including and supporting any sub-ranges or discrete values (which may or may not be a whole number) that are within the stated range(s).

### DETAILED DESCRIPTION OF FIGURES

Referring to FIG. 1, there is shown a method 1 of depositing a ABX₃ perovskite film 2 on a glass substrate 3, method comprising the step of co-evaporating a compound 4, ie, AX, located on a crucible 5, and a compound 6, ie, BX₂ located on a crucible 7, wherein the crucibles and substrate are located inside a vacuum chamber 8 at a selected pressure, and wherein the crucibles are heated to different selected temperatures.

### EXAMPLES

Non-limiting examples of the invention will be further described in greater detail by reference to specific Examples, which should not be construed as in any way limiting the scope of the invention.

### Example 1—Fabrication of Perovskite Films

As shown in the schematic of FIG. 1, PbI₂ (3.5 g, obtained from Tokyo Chemical Industry (TCI), Japan) and CH₃NH₃I (2.5 g, obtained from Luminescence Technology (Lumtec) of Taipei, Taiwan) were separately added to two 10 cm³ cylindrical shape crucibles, and the crucibles were placed inside a vacuum chamber. The PbI₂ and CH₃NH₃I were separately heated at selected temperatures, as shown in Table 1, while the chamber pressure was maintained at about 7.3 to about 8.0×10⁻⁴ Pa, to deposit a CH₃NH₃PbI₃ perovskite film on a substrate.

TABLE 1
Deposition parameters are shown including co-evaporation/deposition
times and heating temperature used for PbI₂/CH₃NH₃I
and the resulting deposition rate

| | Heating | Heating | Deposition |
|---|---|---|---|
| Duration | Temperature | Temperature | Rate |
| (minutes) | PbI₂ (° C.) | CH₃NH₃I (° C.) | (nm/minute) |
| 150 | 345 | 122 | 4.5 |
| 90 | 360 | 130 | 7.6 |
| 45 | 380 | 140 | 15.1 |
| 30 | 390 | 150 | 22.7 |
| 25 | 391 | 155 | 27.2 |

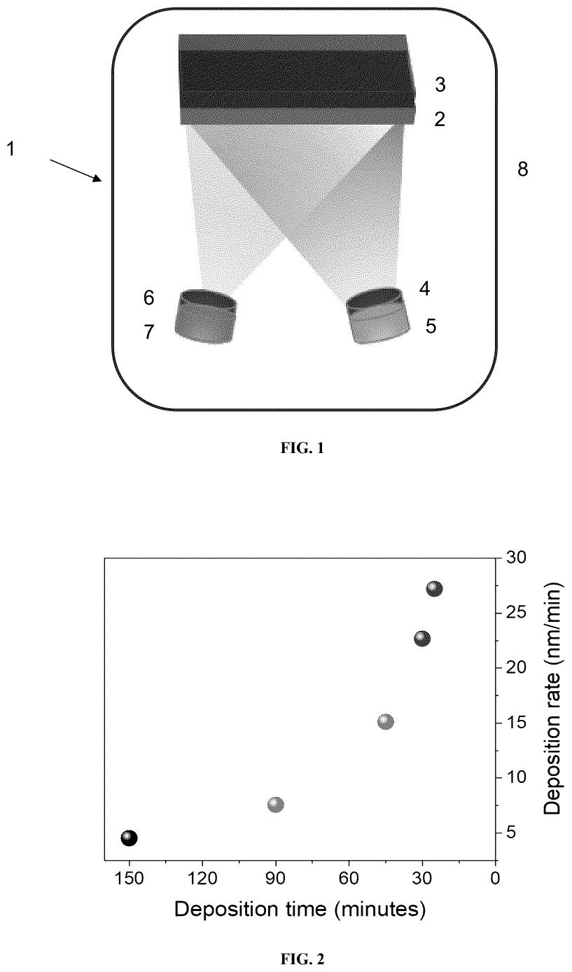

The relationship between the deposition rate and deposition duration is shown in FIG. 2. When the deposition time is 25 minutes, the deposition rate is 27.2 nm/minute, which is about 6 times faster compared to a deposition rate of 4.5 nm/minute, when the deposition time is 150 minutes.

### Example 2—Perovskite Solar Cells and Power Conversion Efficiencies (PCE)

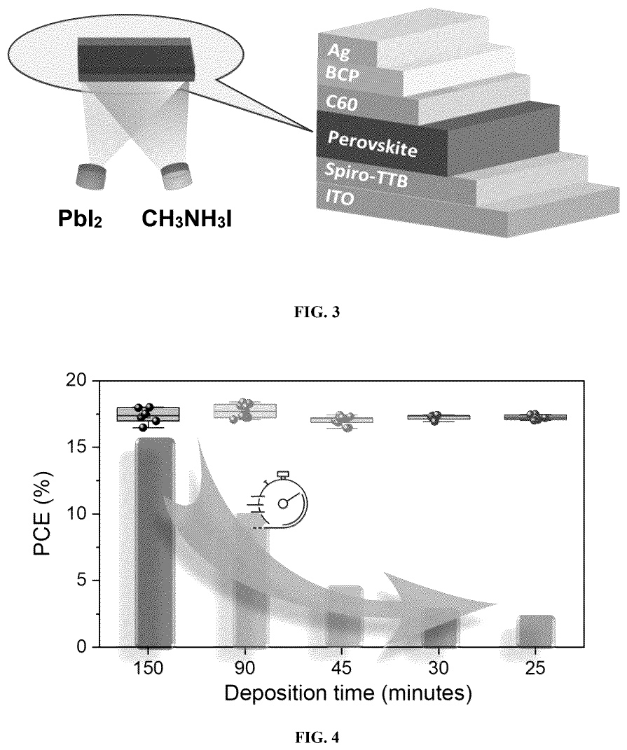

The perovskite films of differing deposition times from Example 1 were incorporated into P-I-N-based perovskite solar cells (PSCs) with an ITO/Spiro-TTB/co-evaporated MAPbI₃/C₆₀/BCP/Ag configuration, as shown in FIG. 3. A comparison between PSCs formed from deposition times of 25 minutes and 150 minutes showed that there was negligible change in the power conversion efficiency (PCE), as shown in FIG. 4. The photovoltaic parameters: open-circuit voltage (Voc), short-circuit current density (Jsc), and fill factor (FF) characteristics of these different PSCs are shown in FIG. 5.

The PCE, Voc, Jsc, and FF values were obtained from current density-voltage (J-V) curves, which were obtained using a Oriel Sol3 ATM solar simulator (obtained from Newport Corporation of California, USA) with a 450-watt xenon lamp, which was calibrated using a standard silicon solar cell.

### Example 3—Comparison to Post-Annealed Sample

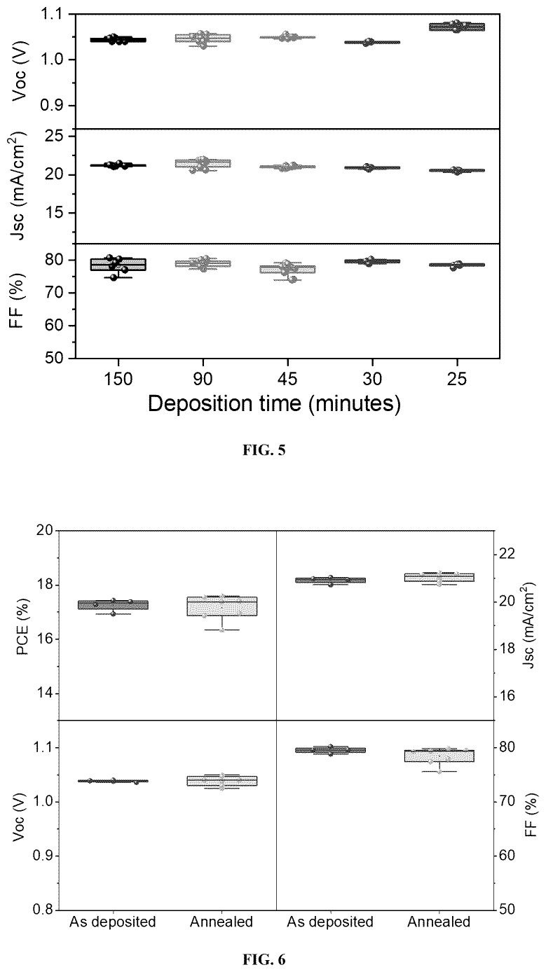

In a typical perovskite fabrication process, post-fabrication annealing (post-annealing) is an important step to obtaining good quality perovskite films. The present disclosure shows that MAPbI₃ perovskite films developed using an accelerated co-evaporation and deposition process do not necessarily require post-annealing. The absence of post-annealing may significantly reduce the total fabrication time as well as reducing energy consumption. As shown in FIG. 6, there is little change to the deposition perovskite film of 25 minutes deposition time with respect to the photovoltaic parameters: PCE, Voc, Jsc, and FF, between the as-deposited perovskite film (without post-annealing) and the post-annealed perovskite film (subjected to 100° C. thermal annealing for 30 minutes). This indicates that there may be an absence of excessive tensile stress in the accelerated deposition process.

### Example 4—Perovskite Properties and Structural Characteristics

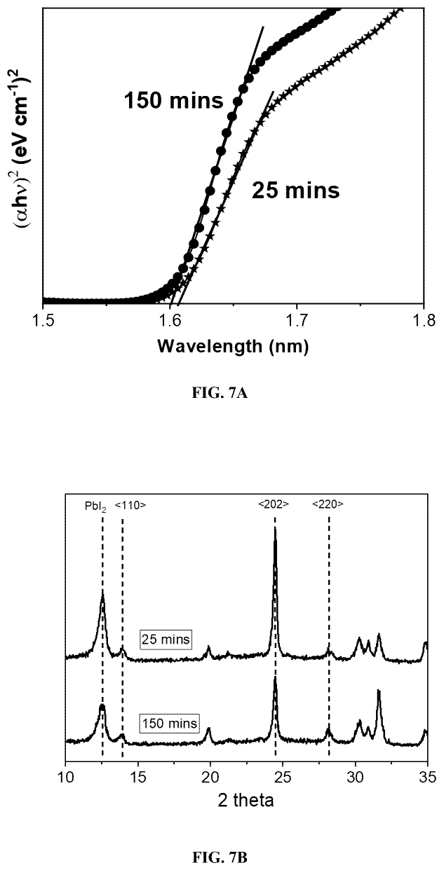

Despite significant changes in the deposition parameters and timing in MAPbI₃ perovskite films prepared in Example 1, the co-evaporated films prepared with deposition times of 25 minutes and 150 minutes demonstrated similar characteristics. As shown in FIG. 7A, these films demonstrate that the perovskite bandgap (˜1.6 eV) was substantially retained when moving from 150 minutes to 25 minutes deposition time. As shown in FIG. 7B, preferential perovskite growth in the <202> direction, a minor ratio variation of approximately 15% between PbI₂ and perovskite is observed when the deposition duration is reduced from 150 minutes to 25 minutes. When the ratio of PbI₂ to MAI is 1:1, no excess PbI₂ is detected in the XRD pattern. However, when the molar amount of PbI₂ exceeds that of MAI, the presence of excess PbI₂ begins to appear in the XRD analysis. The present accelerated process demonstrates that a slight variation in excess PbI₂ relative to the perovskite between 150 minutes and 25 minutes deposition (which is a change of about 15% change), does not significantly affect the photovoltaic cell performance.

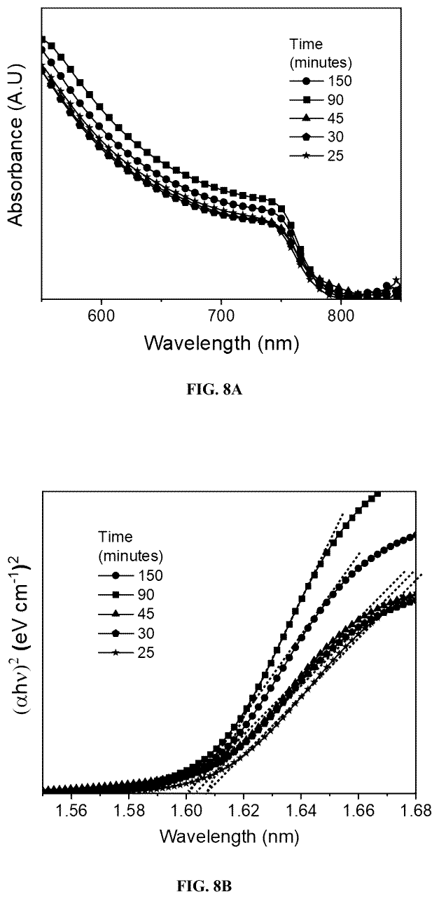

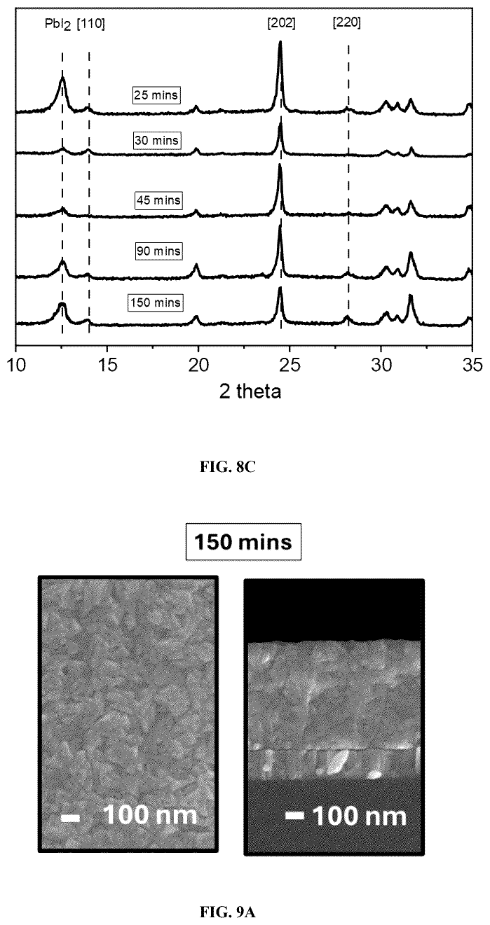

The properties, ie, absorbance, Tauc Plot, and XRD patterns, of perovskite films of different deposition times as produced in Example 1 are shown in FIG. 8A, FIG. 8B and FIG. 8C, demonstrating that the bandgap obtained for all different deposition times was found to be at ˜1.6 eV with a preferred orientation at <202>.

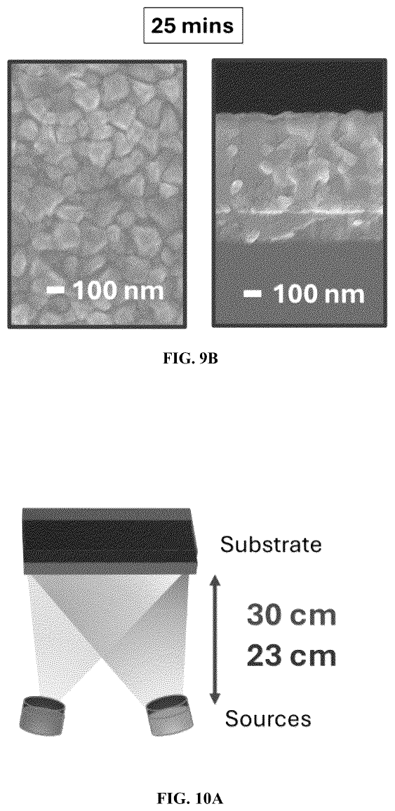

In terms of morphology, the perovskite film produced a deposition time of 150 minutes comprises smaller grains, while the perovskite film produced using the deposition time of 25 minutes comprises larger grains—this may be observed from the top view and cross-sectional view of these perovskite films as shown in the FESEM images of FIG. 9A (deposition time 150 minutes) and FIG. 9B (deposition time 25 minutes). This variation in morphology may be driven by the change in the PbI₂ and perovskite ratio in the film produced using the accelerated deposition duration.

### Example 5—Distance Effects

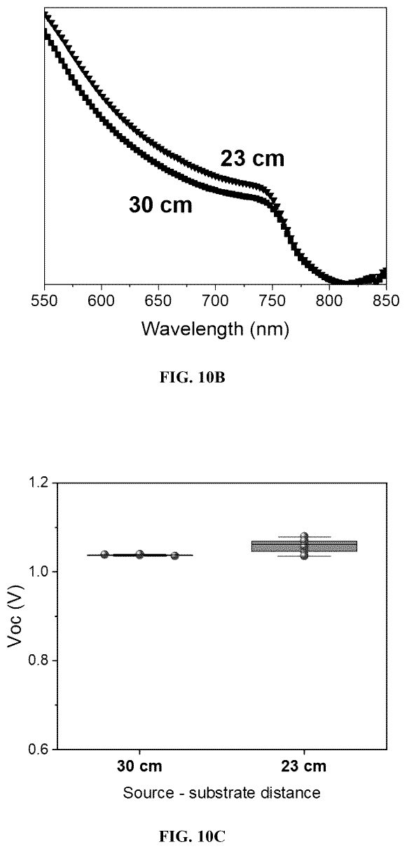

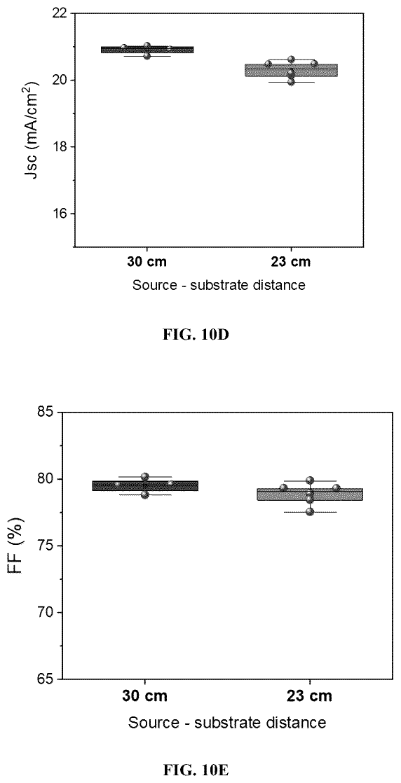

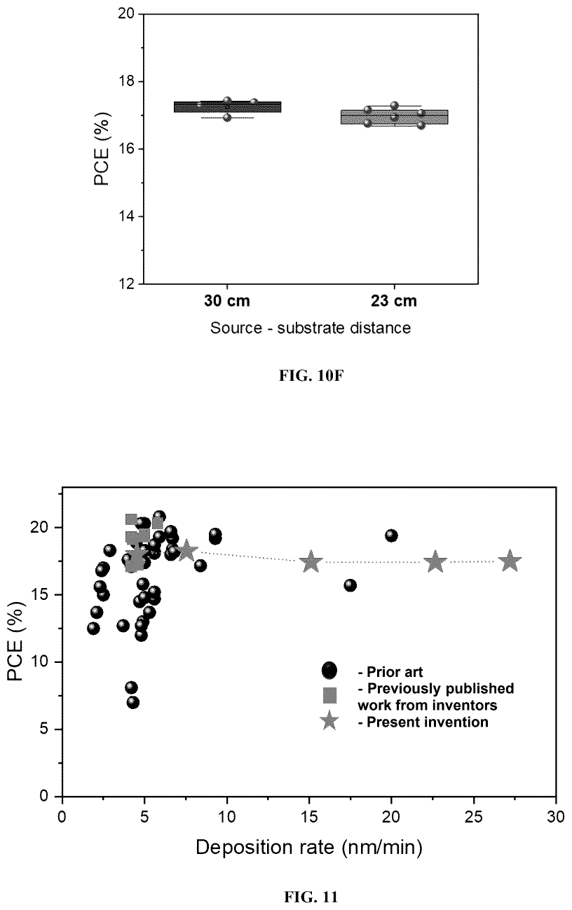

The distance between the source, eg, in the form of crucibles, and the substrate does not appear to significantly the quality of the film produced. By reducing the substrate-source distance from 30 cm to 23 cm, as shown in FIG. 10A, a slight increase in the absorbance was observed which may correspond to the increasing thickness, as shown in FIG. 10B. Despite the change in film thickness, the photovoltaic parameters Voc, Jsc, FF, and PCE were relatively constant between products produced with different distances, as shown in FIG. 10C, FIG. 10D, FIG. 10E, and FIG. 10F.

### Comparative Example 1—Comparison to Previously Disclosed Films

As shown in FIG. 11, the present disclosure provides co-evaporated MAPbI₃ films having power conversion efficiency (PCE) results which surpass those previously disclosed. The presently disclosed perovskite film allows for a significantly shortened process. For example, as disclosed in Piot et al. (ACS Energy Lett. 2023, 8, 11, 4711-4713), a deposition time of 20 nm/min was achieved, and as disclosed in Arivazhagan et al. (Solar Energy, 2019, 181, 339-344), a deposition time of 17.5 nm/minute was achieved. The slight reduction in PCE in the present invention when the deposition time is changed from about 7.6 nm/minute to about 27.2 nm/minute may be accounted for different device perovskite device configurations (eg, N-I-P vs P-I-N) and the absence of post-treatment using any passivator molecule.

The present invention may provide a relatively more controlled deposition process compared to the prior art. As an example, the use of temperature control for both PbI₂ and MAI, and the use of consistent initial powder conditions (in weight and batch) prior to deposition may provide a simpler deposition approach, compared to prior art examples which may rely primarily on a precise rate control of PbI₂. Furthermore, the present invention may provide flexibility in varying the source-to-substrate distance to enable process acceleration, while prior art examples primarily involve a fixed source-to-substrate distance.

### INDUSTRIAL APPLICABILITY

The perovskite film produced by the method as described herein may be incorporated into a photovoltaic cell, which may be used to generate electric power from light.

It will be apparent that various other modifications and adaptations of the invention will be apparent to the person skilled in the art after reading the foregoing disclosure without departing from the spirit and scope of the invention and it is intended that all such modifications and adaptations come within the scope of the appended claims.

1. A method of depositing a perovskite film on a substrate, the perovskite having a formula ABX₃, the method comprising the step of co-evaporating a compound of formula AX and a compound of formula BX₂ onto the substrate,
wherein:
A is selected from one or more monovalent metal cations or organic cations;
B is selected from one or more metal cations or metalloid cations; and
X is selected from one or more halide anions or pseudohalide anions.

2. The method of claim 1, wherein:
A is selected from Cs⁺, Rb⁺, K⁺, CH₃NH₃⁻, [HC(NH₂)₂]⁺, ethylammonium, guanidinium, or a combination thereof;
B is selected from Pb²⁺, Sn²⁺, Ge²⁺, Be²⁺, Mn²⁺, Cu²⁺, Sb²⁺, or a combination thereof, and
X is selected from Cl⁻, Br⁻, I⁻, SCN⁻, CN⁻, or a combination thereof.

3. The method of claim 1, wherein the co-evaporating step is undertaken for a time duration of less than about 90 minutes.

4. The method of claim 1, wherein the co-evaporating step comprises the step (a1) of heating the compound of formula AX to a temperature of between about 60° C. to about 700° C.

5. The method of claim 1, wherein the co-evaporating step comprises the step (a1) of heating the compound of formula AX to a temperature of between about 130° C. to about 180° C.

6. The method of claim 1, wherein the co-evaporating step comprises the step (a2) of heating the compound of formula BX₂ to a temperature of between about 200° C. to about 600° C.

7. The method of claim 1, wherein the co-evaporating step comprises the step (a2) of heating the compound of formula BX₂ to a temperature of between about 350° C. to about 425° C.

8. The method of claim 1, wherein the method is conducted in a vacuum chamber.

9. The method of claim 8, wherein the vacuum chamber is operated at a pressure maintained between about 1×10⁻⁵ Pa to about 1×10⁻² Pa.

10. The method of claim 1, wherein the mole ratio of the compound of formula AX to the compound of formula BX₂ is between about 8:1 to about 1:2.

11. The method of claim 1, wherein the perovskite film is deposited on the substrate at a deposition rate of greater than about 5 nm/minute.

12. The method of claim 1, wherein the compound of formula AX and the compound of formula BX₂ are placed on separate sources.

13. The method of claim 12, comprising the step of varying the distance from each source to the substrate.

14. The method of claim 1, wherein the substrate is coated glass.

15. The method of claim 1, wherein the method does not comprise post-annealing the deposited perovskite film to the substrate.

16. A perovskite film produced by the method of claim 1.

17. The perovskite film of claim 16, wherein the perovskite has a grain size of between about 20 nm to about 300 nm.

18. The perovskite film of claim 16, having a thickness of between about 100 nm to about 1200 nm.

19. A photovoltaic cell comprising the perovskite film of claim 16.

20. The photovoltaic cell of claim 19, having a power conversion efficiency (PCE) of over about 5%.
